(19) United States
(12) Patent Application Publication
(10) Pub. No.: US 2026/0314144 A1
(43) Pub. Date: Oct. 8, 2026

(54) STACKED OPTOELECTRONIC µ-IC DEVICE

(71) Applicant: ams-OSRAM International GmbH, Regensburg (DE)

(72) Inventor: Thomas Schwarz, Regensburg (DE)

(21) Appl. No.: 19/481,790

(22) PCT Filed: May 7, 2024
(86) PCT No.: PCT/EP2024/062661

§ 371 Date: Nov. 5, 2025

(30) Foreign Application Priority Data
May 10, 2023 (DE) 10 2023 112 352.1

(51) Int. Cl. H10H 29/49; H10H 29/01; H10H 29/24

(52) U.S. Cl. CPC H10H 29/49; H10H 29/012; H10H 29/24

(57) ABSTRACT

In an embodiment an optoelectronic device includes a first integrated circuit having first contact pads configured for electrically contacting and/or operating the optoelectronic device and second contact pads, a second integrated circuit arranged on the first integrated circuit having at least third contact pads electrically coupled to at least some of the second contact pads, and an optoelectronic component arranged on the first or second integrated circuit and being electrically coupled to the first or second integrated circuit, wherein the first integrated circuit includes a first functionality configured for operating the optoelectronic component and the second integrated circuit includes a second functionality configured for operating the optoelectronic component.

### CROSS-REFERENCE TO RELATED APPLICATIONS

This patent application is a national phase filing under section 371 of PCT/EP2024/062661, filed May 7, 2024, which claims the priority of German patent application no. 10 2023 112 352.1, filed May 10, 2023, each of which is incorporated herein by reference in its entirety.

### TECHNICAL FIELD

The present invention concerns an optoelectronic device, a transparent panel comprising at least one of the optoelectronic devices, as well as a method for manufacturing the optoelectronic device.

### BACKGROUND

Transparent optoelectronic foils, which are foils comprising integrated emitters and/or detectors, become more and more interesting for several applications such as for example laminated glass panels, displays and further intelligent transparent devices. In such optoelectronic foils driver(s) are needed for desired functionalities of the foil. The more functionality is desired, the larger the drivers (μICs) need to be (e. g. 250×250 μm size), which in turn results in an undesired lower transparency of the foil.

### SUMMARY

Embodiments provide an optoelectronic device, a transparent panel comprising at least one of the optoelectronic devices, as well as a method for manufacturing the optoelectronic device, by which a high transparency of the transparent panel can be provided while providing a high functionality at the same time.

Embodiments provide a reduction of the lateral dimensions of the necessary driver per optoelectronic device by splitting the driver into at least two portions and stack these at least two portions above of each other. An optoelectronic component comprised by the optoelectronic device may also be stacked with these at least two driver portions to further reduce the lateral footprint of the device.

According to a first embodiment an optoelectronic device is provided comprising a first integrated circuit and a second integrated circuit arranged on the first integrated circuit. The first integrated circuit comprises first contact pads for electrically contacting and/or operating the optoelectronic device and second contact pads. The second integrated circuit comprises third contact pads electrically coupled to at least some of the second contact pads of the first contact pad, thus the first and second integrated circuit are electrically coupled to each other. The optoelectronic device further comprises an optoelectronic component arranged on the first or second intergraded circuit, wherein the optoelectronic component is electrically coupled to the first or second intergraded circuit, and in particular to fourth contact pads of the first or second intergraded circuit. The first integrated circuit thereby comprises a first functionality or sub-functionality for operating the optoelectronic component and the second integrated circuit comprises a second functionality or sub-functionality for operating the optoelectronic component.

The first functionality or sub-functionality can for example be analogue functions for operating the optoelectronic component and the second functionality or sub-functionality can for example be digital functions for operating the optoelectronic component. For example, the first integrated circuit may be an analogue circuit, whereas the second integrated circuit may be a digital circuit. However, the order can also be the otherer way around or both integrated circuits can also be of the same type. The same can apply to further integrated circuits that may be comprised by the optoelectronic device.

In some embodiments, the optoelectronic component is arranged adjacent to the second integrated circuit on the first integrated circuit and is electrically coupled to fourth contact pads of the first integrated circuit. Thus, the first integrated circuit comprises first contact pads for electrically contacting and/or operating the optoelectronic device, second contact pads at least some of which are electrically coupled to the second integrated circuit, as well as fourth contact pads electrically coupled to the optoelectronic component.

In some embodiments, the optoelectronic component is arranged on the second integrated circuit opposite the first integrated circuit electrically coupled to fourth contact pads of the second integrated circuit. Thus, the second integrated circuit comprises third contact pads electrically coupled to at least some of the second contact pads, as well as fourth contact pads electrically coupled to the optoelectronic component.

In some embodiments, the optoelectronic device further comprises at least a third integrated circuit arranged adjacent to the second integrated circuit on the first integrated circuit comprising fifth contact pads electrically coupled to at least some of the second contact pads. The optoelectronic component can in such a case be arranged on the first integrated circuit adjacent to the second and third integrated circuit, or the optoelectronic component can be arranged on the second or the third integrated circuit. The respective integrated circuit then comprises fourth contact pads electrically coupled to the optoelectronic component.

In some embodiments, the optoelectronic device further comprises at least a third integrated circuit arranged between the first and the second integrated circuit comprising fifth contact pads electrically coupled to at least some of the third and/or second contact pads. The optoelectronic component can in such a case be arranged on the first integrated circuit adjacent to the stack of the second and third integrated circuit, or the optoelectronic component can be arranged on top of the stack of the second and third integrated circuit on the second integrated circuit. The respective integrated circuit then comprises fourth contact pads electrically coupled to the optoelectronic component. The third integrated circuit can be electrically connected to both the first and second integrated circuit by means of the same electric contacts, can be electrically connected to both the first and second integrated circuit by means of different electric contacts, or can be connected to only one of the first and second integrated circuit. For example, the third integrated circuit can be electrically connected to the first and/or second integrated circuit in a parallel way and/or the third integrated circuit can be electrically connected to the first and/or second integrated circuit in a serial way.

In some embodiments, the optoelectronic component and/or the second integrated circuit and/or the third integrated circuit are arranged on the same side of the first integrated circuit as the first contact pads. This can in particular mean that at least the first integrated circuit does not comprise any contact vias through the material of the first integrated circuit, which makes the first integrated circuit cheaper in production. The same can apply to the second and/or third integrated circuit. In addition, such an arrangement of the optoelectronic component with regard to the first contact pads allows the optoelectronic device to be used as a so called “down” emitter or detector. The light emitting area or light detection area of the optoelectronic component can in such a case for example point in the direction of a carrier substrate the optoelectronic component is arranged on.

In some embodiments, the first integrated circuit and/or the second integrated circuit and/or the third integrated circuit are electrically contactable from only one of its sides. This as aforementioned embodiment can for example mean that the first and/or second and/or third integrated circuit does not comprise any contact vias through the material of the respective integrated circuit, which makes the integrated circuit cheaper in production. Electric contacts between the integrated circuits and between the respective integrated circuit and the optoelectronic component can be realized by the two contactable sides facing each other or by means of electric contacts along at least one side surface of the respective element to be electrically coupled. It is however also conceivable that one or more than one of aforementioned elements is electrically contactable from only one of its sides and at least another one of aforementioned elements is electrically contactable from more than one of its sides.

In some embodiments, the second integrated circuit and/or the third integrated circuit are electrically coupled to the first integrated circuit by means of conductive interconnects along at least one side surface of the respective integrated circuit electrically coupling at least some of the second contact pads with the third and/or fifth contact pads. In this case the second integrated circuit and/or the third integrated circuit can for example be contactable from only one of its sides and an electrically coupling can be achieved by means of for example planar interconnects extending from the second contact pads of the first integrated circuit along at least a side surface of the second and/or third integrated circuit to the third and/or fifth contact pads.

In some embodiments, the optoelectronic component is a light emitting element such as a μ-LED. A μ-LED is in particular a small light emitting diode (LED) configured to emit light of a desired wavelength or wavelength range with edge lengths smaller than 200 μm, smaller than 100 μm, smaller than 50 μm, smaller than 25 μm or smaller than 10 μm. For example the μ-LED can comprise a rectangular cross section with dimensions of 110 μm×60 μm. The μ-LED can be horizontally contactable meaning that contact pads for electrically contacting the μ-LED are arranged on the same side of the μ-LED, or can be vertically contactable meaning that contact pads for electrically contacting the μ-LED are arranged on opposing sides of the μ-LED.

The optoelectronic component can however also be a sensor or μ-sensor configured to detect light of a desired wavelength or wavelength range with edge lengths smaller than 200 μm, smaller than 100 μm, smaller than 50 μm, smaller than 25 μm or smaller than 10 μm. For example the μ-sensor can comprise a rectangular cross section with dimensions of 110 μm×60 μm. The μ-sensor can be horizontally contactable meaning that contact pads for electrically contacting the μ-sensor are arranged on the same side of the μ-sensor, or can be vertically contactable meaning that contact pads for electrically contacting the μ-sensor are arranged on opposing sides of the μ-sensor.

In some embodiments, the optoelectronic device comprises a plurality of optoelectronic components arranged on the first or second integrated circuit electrically coupled to fourth contact pads. In case of the optoelectronic device comprising more than one optoelectronic component, at least one optoelectronic component can be a light emitting element and at least one optoelectronic component can be a light detecting element. It can also be conceivable that at least one of the optoelectronic component is arranged on the first integrated circuit and at least one other optoelectronic component is arranged on the second integrated circuit. In such a case both the first and second integrated circuit can comprise fourth contact pads electrically coupled to a respective optoelectronic component.

According to another embodiment a transparent panel such as a transparent display or glazing is provided. The transparent panel comprises at least one optoelectronic device according to some of aforementioned embodiments as well as a transparent carrier substrate and a conductive structure arranged on the carrier substrate, wherein the at least one optoelectronic device is arranged on the conductive structure being electrically coupled to the same. The carrier substrate can for example be a polyethylene terephthalate (PET) or a glass layer. The carrier substrate can for example comprise a transparency of greater than 80% for light with a wavelength of 530 nm when coupling the light from the carrier substrate into air.

The at least one optoelectronic device can be electrically coupled to the conductive structure by means of for example solder bumps arranged between the at least one optoelectronic device and in particular between the first contact pads or the first integrated circuit of the at least one optoelectronic device and the conductive structure. Such a connection can in addition to the electrical connection provide a certain mechanical connection between the optoelectronic device and the conductive structure. However, the at least one optoelectronic device can also be electrically coupled to the conductive structure by means of for example an electrically conductive adhesive, a nanowire structure embedded in an adhesive, or a plated/printed interconnect on top of an adhesive. The adhesive can in such a case provide a certain mechanical connection between the optoelectronic device and the conductive structure whereas the conductive components within or on top of the adhesive can provide the electrical connection.

In some embodiments, the transparent panel further comprises a transparent cover layer encapsulating the optoelectronic device and the conductive structure on carrier substrate. The transparent cover layer can for example be a layer of polyvinyl butyral (PVB) or silicone or parylene.

In some embodiments, the at least one optoelectronic device is configured to emit light through the carrier substrate or detect light emitted trough the carrier substrate onto the optoelectronic component. This can in particular result from the arrangement of the optoelectronic device in relation to the carrier substrate.

In some embodiments, the conductive structure is a mesh, in particular metal mesh, arranged on the carrier substrate. The mesh can in particular be configured to not or not hardly influence the transparency of the transparent panel at least for the eye of a viewer of the transparent panel. The mesh can therefore comprise a coating, in particular a black coating to reduce the reflectance of the material of the mesh which provides a higher transparency at least for the perception of a viewer of the transparent panel. The mesh comprises a plurality of portions electrically isolated from one another, each electrically contacting a first contact pad of an optoelectronic device.

According to another embodiment a method for manufacturing an optoelectronic device is provided. The method comprises the steps:
providing a first integrated circuit substrate;
processing the integrated circuit substrate to receive at least a first integrated circuit;
providing first and second contact pads on the at least first integrated circuit;
providing a second integrated circuit on the at least first integrated circuit comprising third contact pads electrically coupled to at least some of the second contact pads;
providing an optoelectronic component on the first or second intergraded circuit being electrically coupled to the first or second intergraded circuit;
wherein the first integrated circuit comprises a first functionality for operating the optoelectronic component and the second integrated circuit comprises a second functionality for operating the optoelectronic component.

The optoelectronic device manufactured by such a method is in particular an optoelectronic device according to some of aforementioned embodiments.

In some embodiments, the step of providing the second integrated circuit on the at least first integrated circuit comprises providing an adhesive on the at least first integrated circuit and a compression bonding of the second integrated circuit on the at least first integrated circuit such that third contact pads of the second integrated circuit come into electrical and mechanical contact with the respective second contact pads of the first integrated circuit.

In some embodiments, the method further comprises a step of providing a third integrated circuit on the at least first integrated circuit comprising third contact pads electrically coupled to at least some of the second contact pads. The step of providing the second integrated circuit can then for example take place after the step of providing the third integrated circuit, and the second integrated circuit can for example be provided on the third integrated circuit such that the third integrated circuit is arranged between the first and second integrated circuit. The third integrated circuit can however also be provided on the first integrated circuit adjacent to the second integrated circuit.

In some embodiments, the method further comprises a step of back etching the integrated circuit substrate on a side opposite the second integrated circuit and providing a reflective coating on the etched surface. By this an emission of light through the at least first integrated circuit can be prevented, and light emitted in the direction of the first integrated circuit can be back reflected.

In some embodiments, the method further comprises a step of providing a temporary carrier substrate as well as a release layer on the integrated circuit substrate or the reflective coating on a side opposite the second integrated circuit. By means of the temporary carrier substrate and the release layer, the optoelectronic device can in a subsequent step be transferred to a respective target substrate, such as for example the carrier substrate of the transparent panel according to some embodiments of the proposed principle.

In some embodiments, the step of processing the integrated circuit substrate comprises a processing to receive a plurality of first integrated circuits, the step of providing a second integrated circuit on the at least first integrated circuit comprises providing each a second integrated circuit on each of the first integrated circuits, and the step of providing an optoelectronic component comprises providing each an optoelectronic component on a respective first or second intergraded circuit. Hence the method can comprise the manufacturing of several optoelectronic devices at the same time.

In some embodiments, the method further comprises a step of testing the optoelectronic device(s), in particular before separating the optoelectronic devices from each other. The step of testing can for example comprise applying of a voltage/current by means of testing probe(s).

In some embodiments, the method further comprises a step of separating individual optoelectronic devices each comprising a first integrated circuit, a second integrated circuit, optionally a third or further integrated circuit and an optoelectronic component. The separation can for example comprise a step of sawing through the integrated circuit substrate. In particular, the step of separating individual optoelectronic devices can take place after the step of providing the temporary carrier substrate as well as the release layer and the separation/sawing can be done down to the release layer but not trough the release layer and the temporary carrier substrate. Hence the separated optoelectronic devices can still be connected by means of the release layer and the temporary carrier substrate can be individually released from the release layer and the temporary carrier substrate.

According to another embodiment a method for manufacturing a transparent panel comprising at least one optoelectronic device according to some of aforementioned embodiments is provided. The method comprises the steps:
providing a transparent carrier substrate;
providing a conductive structure on the carrier substrate; and
providing at least one optoelectronic device according to some of aforementioned embodiments on the electrical structure such that the at least one optoelectronic device is arranged on the conductive structure being electrically coupled to the same.

In some embodiments, the step of providing the at least one optoelectronic device comprises a laser LIFT process to release the at least one optoelectronic device from a temporary carrier substrate and a release layer.

In some embodiments, the method further comprises a step of coating the carrier substrate, the conductive structure and the at least one optoelectronic device with a transparent protective coating.

Advantages that can result from such an optoelectronic device/transparent panel can for example be:
small footprint with a high functionality;
high transparency;
cheap interconnect processes can be used for both, optoelectronic component and integrated circuits.

### BRIEF DESCRIPTION OF THE DRAWINGS

Further embodiments and embodiments in accordance with the proposed principle will become apparent in relation to the various embodiments and examples described in detail in connection with the accompanying drawings in which

FIG. 1 shows a top view of an optoelectronic device in accordance with some embodiments of the proposed principle;

FIGS. 2A and 2B show each a cross section of the optoelectronic device of FIG. 1 integrated into a transparent panel in accordance with some embodiments of the proposed principle;

FIG. 3 shows an exemplary functionality diagram of an optoelectronic device in accordance with some embodiments of the proposed principle;

FIGS. 4 and 5 show each a top view of a further embodiment of an optoelectronic device in accordance with some embodiments of the proposed principle;

FIGS. 6A and 6B show a top and a side view of a further embodiment of an optoelectronic device in accordance with some embodiments of the proposed principle;

FIGS. 7A and 7B show a top and a side view of a further embodiment of an optoelectronic device in accordance with some embodiments of the proposed principle;

FIGS. 8A to 8C show top views and a side view of a further embodiment of an optoelectronic device in accordance with some embodiments of the proposed principle;

FIGS. 9 to 11 show each a side view of a further embodiment of an optoelectronic device in accordance with some embodiments of the proposed principle;

FIGS. 12A to 12G show steps of a method for manufacturing an optoelectronic device in accordance with some embodiments of the proposed principle;

FIGS. 13A and 13B show steps of a method for manufacturing a transparent panel in accordance with some embodiments of the proposed principle;

FIGS. 14A to 14E show each a side view of an embodiment of a transparent panel in accordance with some embodiments of the proposed principle; and

FIG. 15 shows a top view of an embodiment of a transparent panel in accordance with some embodiments of the proposed principle.

### DETAILED DESCRIPTION OF ILLUSTRATIVE EMBODIMENTS

The following embodiments and examples disclose various embodiments and their combinations according to the proposed principle. The embodiments and examples are not always to scale. Likewise, different elements can be displayed enlarged or reduced in size to emphasize individual embodiments. It goes without saying that the individual embodiments and examples shown in the figures can be combined with each other without further ado, without this contradicting the principle according to the invention. Some embodiments show a regular structure or form. It should be noted that in practice slight differences and deviations from the ideal form may occur without, however, contradicting the inventive idea.

In addition, the individual figures and embodiments are not necessarily shown in the correct size, nor do the proportions between individual elements have to be essentially correct. Some embodiments are highlighted by showing them enlarged. However, terms such as “above”, “over”, “below”, “under” “larger”, “smaller” and the like are correctly represented with regard to the elements in the figures. So it is possible to deduce such relations between the elements based on the figures.

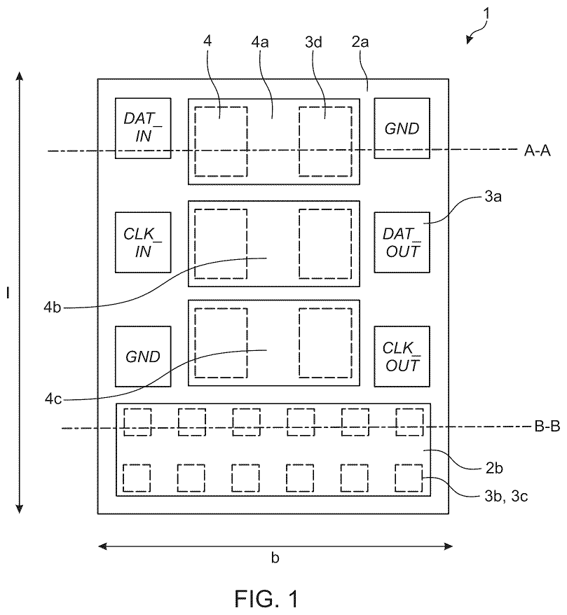

FIG. 1 shows a top view of a first embodiment of an optoelectronic device 1 in accordance with some embodiments of the proposed principle. The optoelectronic device 1 comprises a first integrated circuit 2a, a second integrated circuit 2b, and three optoelectronic components 4a, 4b, 4c. The first integrated circuit 2a comprises first contact pads 3a for electrically contacting and operating the optoelectronic device 1, second contact pads 3b, as well as fourth contact pads 3d. The second integrated circuit 2b is arranged on the first integrated circuit 2a and comprises third contact pads 3c facing the second contact pads 3b and being electrically coupled to the second contact pads 3b. The optoelectronic components 4a, 4b, 4c are arranged on the first intergraded circuit 2a adjacent to the second integrated circuit 2b and are each electrically coupled to the first intergraded circuit 2a by means of the fourth contact pads 3d. For example, the three optoelectronic components 4a, 4b, 4c can be configured to emit red, green and blue light forming a so called RGB-pixel. This is however to be understood as exemplary and the optoelectronic components can also be configured to emit and/or detect light of any other colour as well as any other number of optoelectronic components can be used.

The first integrated circuit 2a is dimensioned such that on its top surface there is enough space for accommodating the optoelectronic components 4a, 4b, 4c, the second integrated circuit 2b as well as the first contact pads 3a for electrically contacting and operating the optoelectronic device 1. Each of the optoelectronic components 4a, 4b, 4c and the second integrated circuit 2b thereby covers only a portion of the top surface of the first integrated circuit 2a. In particular, the first integrated circuit 2a comprises a length l and a width b in the μm range. Hence the first integrated circuit 2a can also be called μ-IC.

The first integrated circuit 2a can for example be configured to provide a first functionality or sub-functionality for operating the optoelectronic components 4 whereas the second integrated circuit 2b can for example be configured to provide a second functionality or sub-functionality for operating the optoelectronic components 4. Via the first contact pads 3a it can for example be provided an incoming data signal DAT_IN and an incoming clock signal CLK_IN for programming the optoelectronic components 4, as well as a first potential VDD and a second potential GND for operating the optoelectronic components 4. In addition, the data signal and the clock signal can be passed on by means of the first contact pads 3a in form of an outgoing data signal DAT_OUT and an outgoing clock signal CLK_OUT.

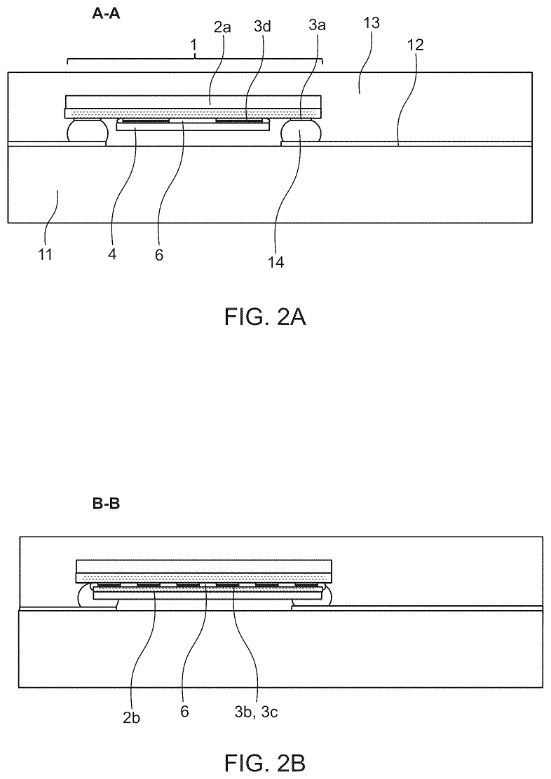

FIGS. 2A and 2B each show a cross section through the optoelectronic device 1 when integrated into a transparent panel 10 in accordance with some embodiments of the proposed principle. FIG. 2A shows a cross section along cutline A-A, whereas FIG. 2B shows a cross section along cutline B-B. Thus, FIG. 2A shows a cross section through the first integrated circuit 2a and one of the optoelectronic components 4a, whereas FIG. 2B shows a cross section through the first integrated circuit 2a and the second integrated circuit 2b.

The optoelectronic device 1 is arranged on a conductive structure 12 on a transparent carrier substrate 11 with the optoelectronic components 4a, 4b, 4c, the second integrated circuit 2b as well as the first contact pads 3a facing the carrier substrate 11. By this an emission of light can be provided through the transparent carrier substrate 11 or light incident on the transparent carrier substrate 11 can be detected by means of the optoelectronic device 1.

The optoelectronic device 1 is electrically coupled to the conductive structure 12 by means of solder balls 14 electrically coupling the first contact pads 3a and the conductive structure 12. On the first integrated circuit 2a an adhesive layer 6 is arranged by means of which the optoelectronic components 4a, 4b, 4c and the second integrated circuit 2b are fixed to the first integrated circuit 2a.

The optoelectronic device 1, the carrier substrate 11 as well as the conductive structure 12 are covered by means of a transparent cover layer 13, which protects the optoelectronic device 1 from external influences. Together with the transparent cover layer 13 the optoelectronic device 1, the carrier substrate 11 as well as the conductive structure 12 forms an intelligent transparent panel, which can be used for projecting light in form of for example text or images and/or for detecting incident light on the panel.

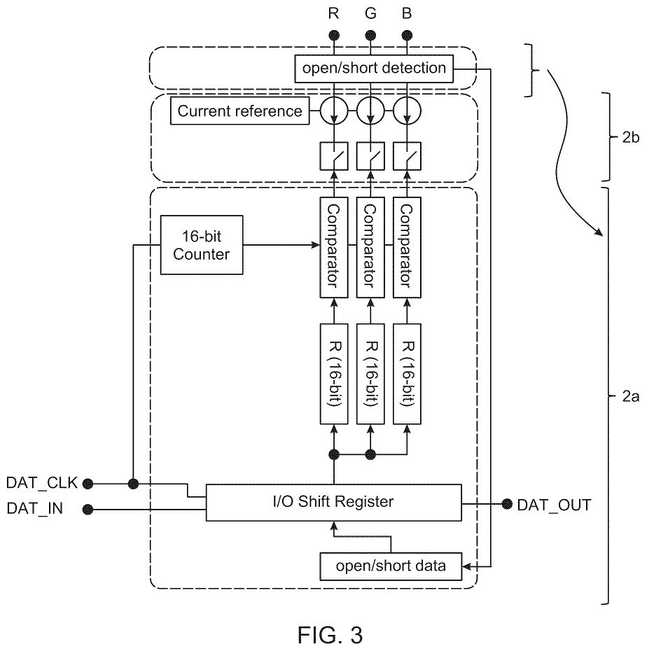

FIG. 3 shows an exemplary functionality diagram of an optoelectronic device in accordance with some embodiments of the proposed principle. In particular FIG. 3 shows the split of different functionalities or sub-functionalities for operating three optoelectronic components R, G, B with regard to the first and second integrated circuit 2a, 2b. R, G, B can in this context for example be understood as each an optoelectronic component configured to emit red, green and blue light. For example the first integrated circuit 2a can be configured to provide all necessary digital circuitry for operating the optoelectronic components 4, whereas the second integrated circuit 2b can be configured to provide all necessary analogue circuitry for operating the optoelectronic components 4. The second integrated circuit 2b can for example provide an adjustable current source for each of the optoelectronic components R, G, B, while the first integrated circuit can for example provide a digital programming of the optoelectronic components R, G, B by means of for example shift registers, counters, comparators and memories.

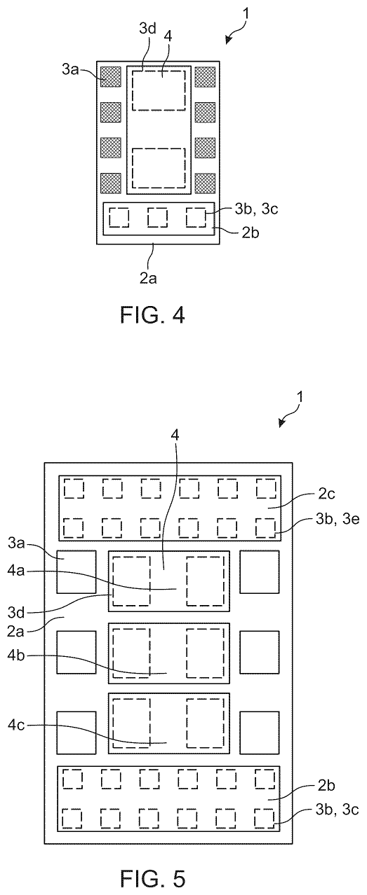

FIG. 4 shows a further embodiment of an optoelectronic device 1 in accordance to some embodiments of the proposed principle. In contrast to the embodiment of FIG. 1, the optoelectronic device 1 comprises only one optoelectronic component 4 arranged on the first integrated circuit 2a. The resulting optoelectronic device 1 can thus be very small comprising its own integrated circuit stack for operation.

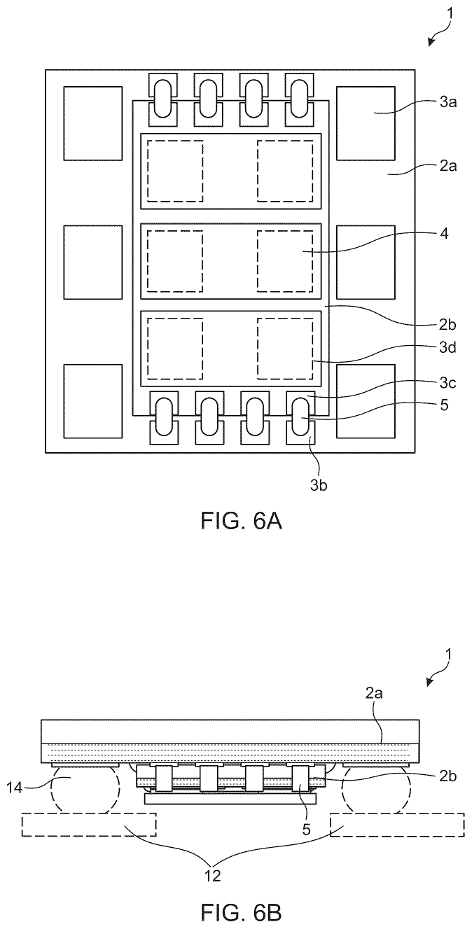

FIG. 5 shows a further embodiment of an optoelectronic device 1 in accordance to some embodiments of the proposed principle. In addition to the embodiment of FIG. 1, the optoelectronic device 1 comprises a third integrated circuit 2c arranged on the first integrated circuit 2a comprising fifth contact pads 3e facing the first integrated circuit 2a and being electrically coupled to some of the second contact pads 3b. The resulting optoelectronic device 1 can thus provide more functionality due to the larger amount of integrated circuit area.

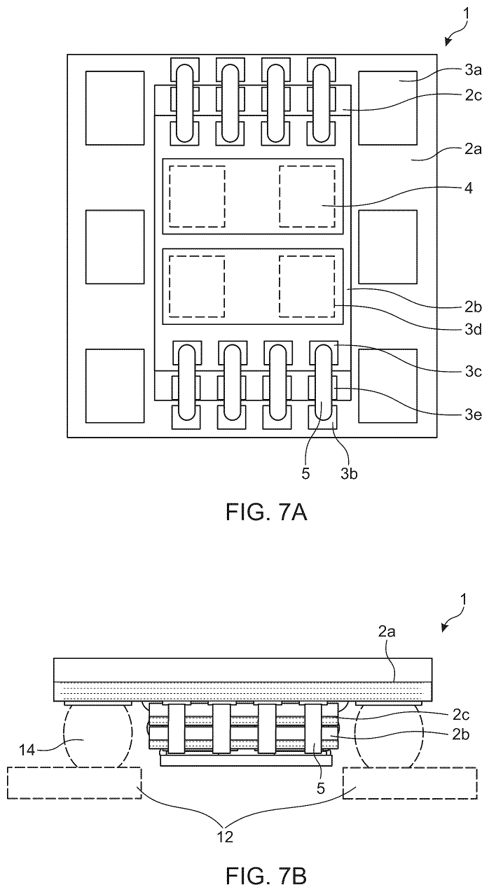

FIGS. 6A and 6B show a top and a side view of a further embodiment of an optoelectronic device 1 in accordance with some embodiments of the proposed principle. In contrast to the embodiment of FIG. 1, the optoelectronic components 4 are arranged on the second integrated circuit 2b and not on the first integrated circuit 2a. Therefore, the second integrated circuit 2b comprises fourth contact pads 3d on a side facing away from the first integrated circuit 2a being electrically coupled to the optoelectronic components 4. The third contact pads 3c of the second integrated circuit 2b are in addition not facing the first integrated circuit 2a but are arranged on the same side as the fourth contact pads 3d. An electric contact between the second and third contact pads is therefore realized by means of conductive interconnects 5 extending from the second to the third contact pads along two opposing side surfaces of the second integrated circuit 2b. The conductive interconnects 5 can for example be metallic redistribution layers (RDLs), metallic planar interconnects or metallic printed interconnects. The resulting optoelectronic device 1 can be smaller but a little bit higher compared to the embodiment shown in FIG. 1.

In FIG. 6B it is indicated how the optoelectronic device 1 can be integrated into a transparent panel, an in particular can be connected to the conductive structure 12 of a transparent panel by means of solder bumps 14. The orientation of the optoelectronic device 1 can thereby be as already described for FIGS. 2A and 2B.

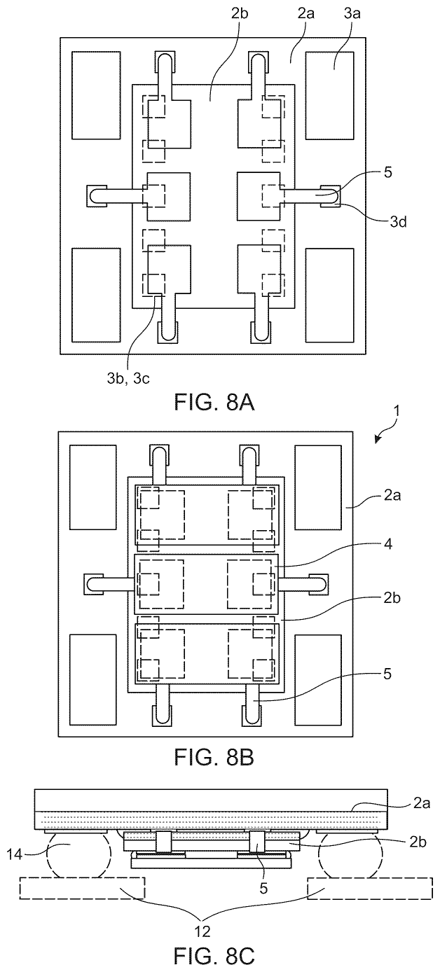

FIGS. 7A and 7B show a top and a side view of a further embodiment of an optoelectronic device 1 in accordance with some embodiments of the proposed principle. In addition to the embodiment of FIGS. 6a and 6B, the optoelectronic device 1 further comprises a third integrated circuit 2c arranged between the first and second integrated circuit. In this specific embodiment, only two optoelectronic components 4 are arranged on the second integrated circuit 2b, which is however only to be understood as exemplary.

The third integrated circuit 2c comprises fifth contact pads 3e arranged on a side of the third integrated circuit 2c opposite the first integrated circuit 2a. The fifth contact pads 3e are electrically coupled to the second contact pads as well as to the third contact pads by means of conductive interconnects 5 extending from the second to the fifth and from the fifth to the third contact pads along two opposing side surfaces of the second and the third integrated circuit. To allow a contacting of each a top surface of the first, second and third integrated circuits, the three integrated circuits are arranged in steps, such that the conductive interconnects 5 are able to contact the second, fifth and third contact pads arranged along the respective edge of the respective integrated circuit.

In FIG. 7B it is indicated how the optoelectronic device 1 can be integrated into a transparent panel, an in particular can be connected to the conductive structure 12 of a transparent panel by means of solder bumps 14. The orientation of the optoelectronic device 1 can thereby be as already described for FIGS. 2A and 2B.

The design to FIGS. 6A to 7B can have the advantage that the first, the second and the optional third integrated circuit can be manufactured without having contact vias through the integrated circuit itself but still provide a contacting on both sides of the second integrated circuit 2b.

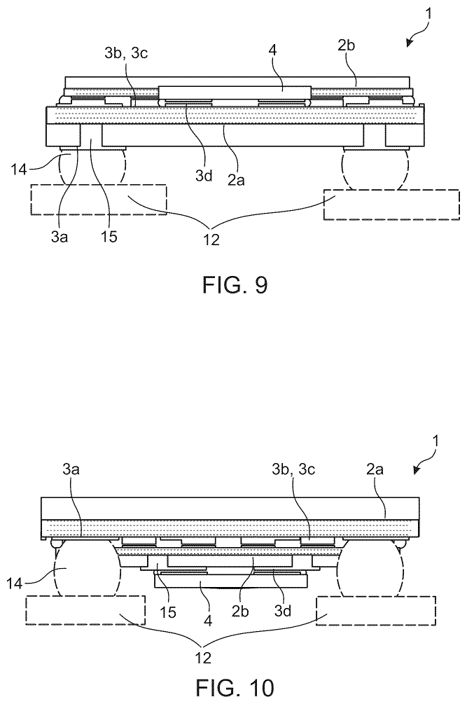

FIGS. 8A to 8C show top views and a side view of a further embodiment of an optoelectronic device 1 in accordance with some embodiments of the proposed principle. FIG. 8A shows an optoelectronic device 1 with a first integrated circuit 2a and a second integrated circuit 2b, wherein second contact pads 3a of the first integrated circuit 2a and third contact pads 3c of the second integrated circuit 2b are facing each other and being electronically connected. The first integrated circuit 2a further comprises first contact pads 3a for electrically contacting and operating the optoelectronic device 1 as well as fourth contact pads 3d for electrically contacting optoelectronic components 4. However, the optoelectronic components 4 are to be arranged on the second integrated circuit 2b and not on the first integrated circuit 2a as shown in FIG. 8B. Therefore conductive interconnects 5 are provided extending from the fourth contact pads onto the second integrated circuit 2b to provide contact pads for the optoelectronic components 4 to be arranged on the second integrated circuit 2b. FIG. 8A shows the optoelectronic device 1 before arranging the optoelectronic components 4 on the second integrated circuit 2b and FIG. 8B shows the optoelectronic device 1 after arranging the optoelectronic components 4 on the second integrated circuit 2b.

Such a design can have the advantage that the first and the second integrated circuit can be manufactured without having contact vias through the integrated circuit itself but still provide a contacting on both sides of the second integrated circuit 2b.

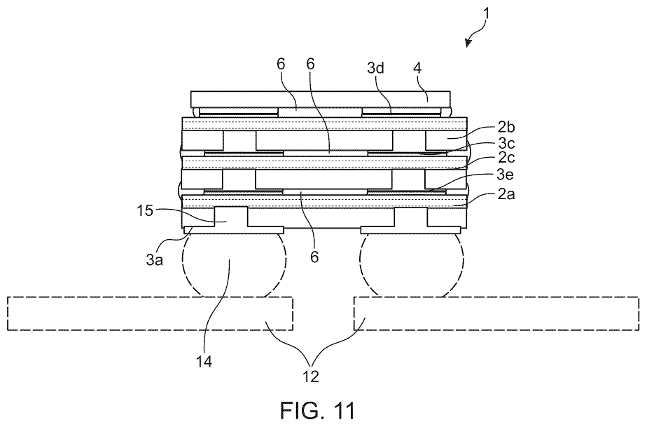

FIG. 9 shows a side view of a further embodiment of an optoelectronic device 1 in accordance with some embodiments of the proposed principle. In this optoelectronic device 1 the first integrated circuit 2a comprises contact vias 15 for guiding the first contact pads 3a to the bottom side of the first integrated circuit 2a opposite the second contact pads 3b. By this the optoelectronic device 1 can be integrated upside down into a transparent panel compared to aforementioned embodiments.

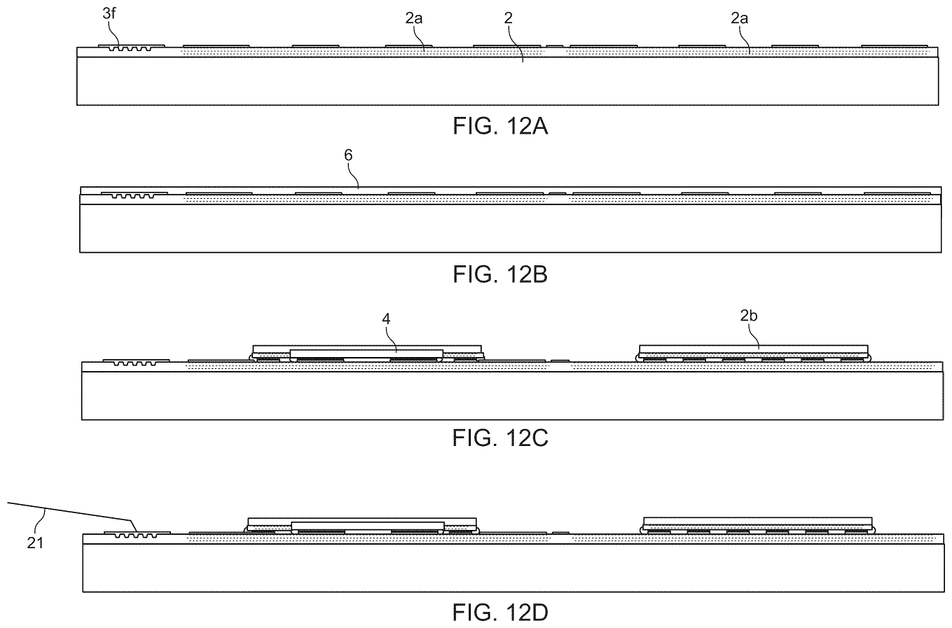

FIG. 10 shows a side view of a further embodiment of an optoelectronic device 1 in accordance with some embodiments of the proposed principle. In this optoelectronic device 1 the second integrated circuit 2b comprises contact vias 15 for guiding the fourth contact pads 3d to a side of the first integrated circuit 2a opposite the third contact pads 3c. By this the optoelectronic component(s) 4 can be arranged on the second integrated circuit 2b without having conductive interconnects alongside surfaces of the second integrated circuit 2b compared to the embodiments of FIGS. 6A and 6B and FIGS. 8A to 8C.

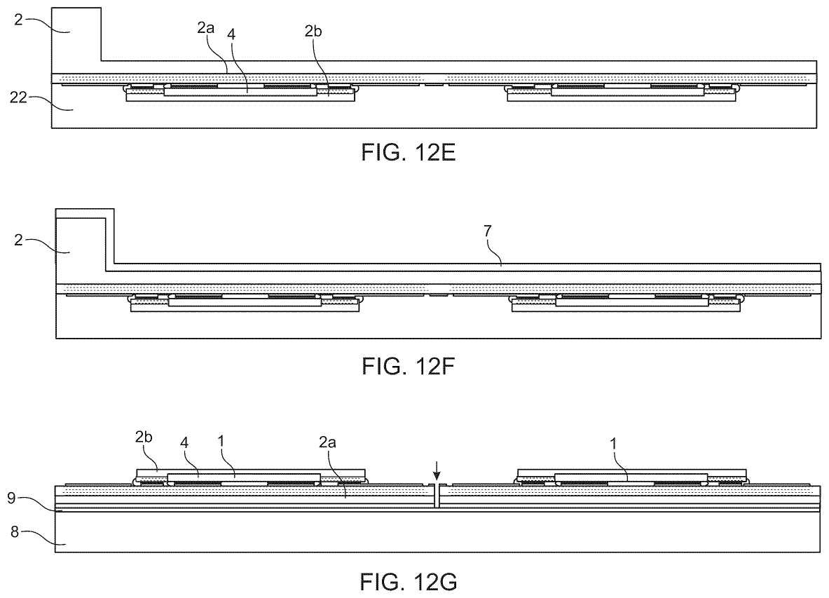

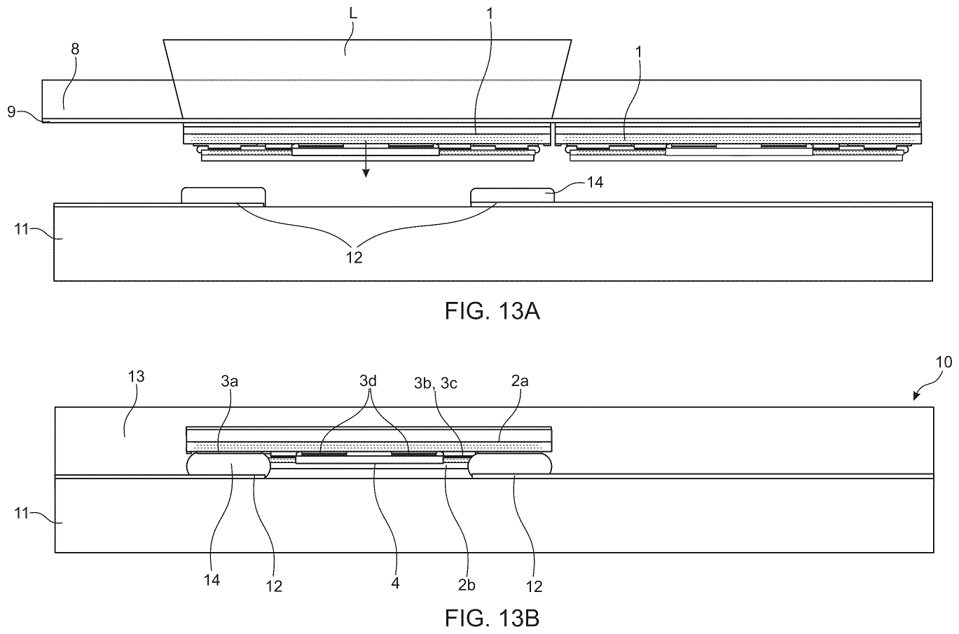

FIG. 11 shows a side view of a further embodiment of an optoelectronic device 1 in accordance with some embodiments of the proposed principle. In this optoelectronic device 1 the first, second and third integrated circuit 2b comprises contact vias 15 for guiding respective contact pads to an opposing side of the respective integrated circuit. By this the integrated circuits can be stacked and the optoelectronic component(s) 4 can be arranged on the second integrated circuit 2b without having conductive interconnects alongside surfaces of the second and third integrated circuit compared to the embodiments of FIGS. 6A and 6B, 7A and 7B and FIGS. 8A to 8C.
FIGS. 12A to 12G show steps of a method for manufacturing an optoelectronic device 1 in accordance with some embodiments of the proposed principle. In a first step, as shown in FIG. 12A, an integrated circuit substrate 2 is provided, which is processed to receive first integrated circuit portions 2a. The processing can for example comprise standard CMOS processing technologies. On the integrated circuit substrate 2 and the first integrated circuit portions 2a respectively, first, second and fourth contact pads as well as sixth contact pads 3f are provided. The contact pads can for example be provided by means of standard pad processing technologies and the pads can for example be of gold or gold alloy.

In a further step, as shown in FIG. 12B, an adhesive layer is provided on the first integrated circuit portions 2a by for example an spin on process. Subsequently, as shown in FIG. 12C, optoelectronic components 4, as well as second integrated circuits 2b are then arranged on the first integrated circuit portions 2a on respective contact pads. The optoelectronic components 4, as well as second integrated circuits 2b can for example be electrically connected to the contact pads by using thermocompression bonding techniques. In addition, excessive material of the adhesive layer 6 is removed by for example O₂ plasma etching (ashing).

The whole structure is then tested in a following step, as shown in FIG. 12D by means of a testing probe 21 contacting the sixth contact pad(s) 3f and applying a current/voltage to it.

As shown in FIG. 12E, the integrated circuit substrate 2 can be thinned from a surface opposite the optoelectronic components 4 and the second integrated circuits 2b by means of for example a TAIKO process. For better handling, a temporary carrier 22 such as for example a grinding carrier (e.g. a tape) can be attached to the side not being thinned. On the resulting back surface, a reflective coating 7/backside metallisation is then provided, as shown in FIG. 12F, of for example Ti, Pd, Pt, Cu nitrides, Cu oxides, Ni, or Rh or any other black resist or dielectric mirror can be provided on the resulting back surface for light protection of the back surface.

Then a temporary carrier substrate 8 as well as a release layer is provided on the thinned surface and the temporary carrier 22 is removed. As shown in FIG. 12G the integrated circuit substrate 2 is then further processed such that optoelectronic devices 1 are separated each comprising a first integrated circuit 2a, a second integrated circuit 2b and an optoelectronic component 4. The separation/singulation can for example be performed by means of sawing down until the release layer 9, indicated by the small arrow.

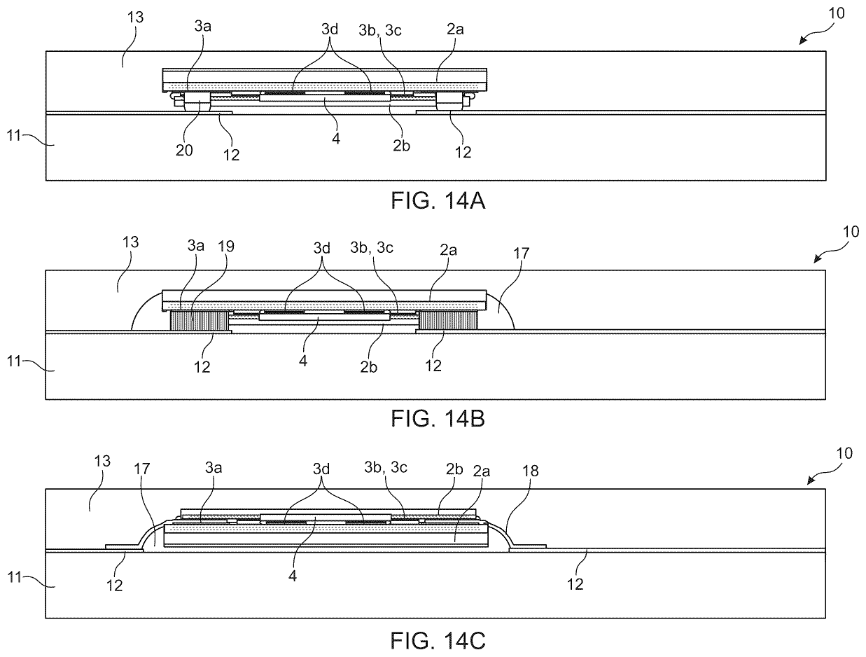

FIGS. 13A and 13B show steps of a method for manufacturing a transparent panel in accordance with some embodiments of the proposed principle, which can in particular be subsequent to the steps of FIGS. 12A to 12G. As shown in FIG. 13A a transparent carrier substrate 11 with a conductive structure 12 on the carrier substrate 11 and solder bumps 14 on the conductive structure 12 is provided. Opposite the solder bumps 14, a temporary carrier substrate 8 with a release layer 9 and optoelectronic devices 1 on top is arranged. The temporary carrier substrate 8 is arranged above the solder bumps 14 such that first contact pads 3a of an optoelectronic device 1 are facing the solder bumps 14. By means of light L, the optoelectronic device 1 is then released from the release layer 9 and falls onto the solder bumps 14 subsequently being electrically connected to the same. This step can in parallel or serial be repeated until the carrier substrate 11 is equipped with a desired amount of optoelectronic devices 1.

As shown in FIG. 13B it is then provided a transparent cover layer on the carrier substrate 11 with the conductive structure 12 and the optoelectronic components 4 arranged on the conductive structure 12. By this the optoelectronic components 4 are encapsulated and protected from external influences.

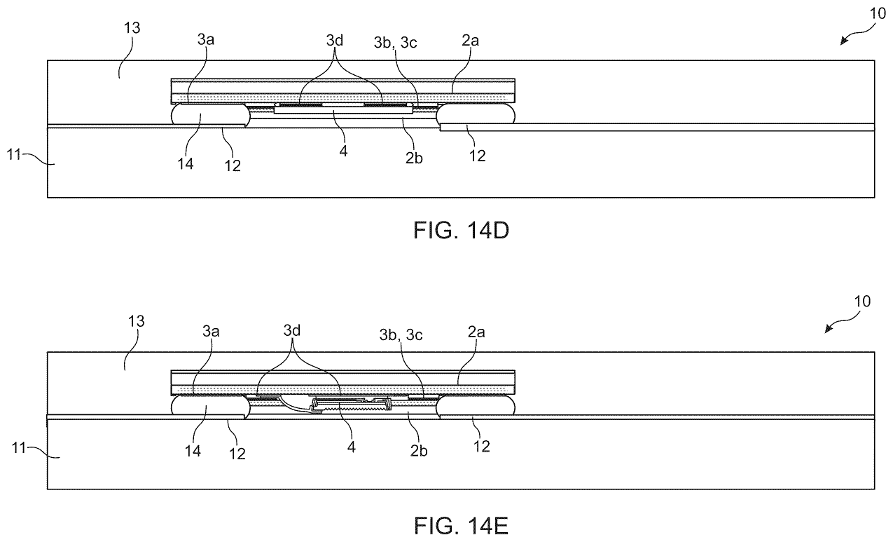

FIGS. 14A to 14E show each a side view of further embodiments of a transparent panel in accordance with some embodiments of the proposed principle and in particular further embodiments of an optoelectronic device 1 in accordance with some embodiments of the proposed principle.

The optoelectronic device 1 of FIG. 14A is electrically connected to the conductive structure 12 by Cu pillars 20 which as solder bumps are easy to be applied on the conductive structure 12. The optoelectronic device 1 of FIG. 14B on the other hand is electrically connected to the conductive structure 12 by means of conductive nanowires 19 encapsulated in an adhesive 17 providing the necessary mechanical stability between the optoelectronic device 1 and the conductive structure 12.

The optoelectronic device 1 of FIG. 14C is glued by means of an adhesive 17 to the carrier substrate 11 upside down compared to aforementioned embodiments and is electrically connected to the conductive structure 12 by means of conductive interconnects 18 plated or printed onto the adhesive 17.

The optoelectronic devices 1 of FIGS. 14D and 14E show embodiments using a horizontally contactable optoelectronic component 4 whereas in the embodiment of FIG. 14E a vertically contactable optoelectronic component 4 with a respective contacting structure to electrically contact the fourth contact pads 3d is used.

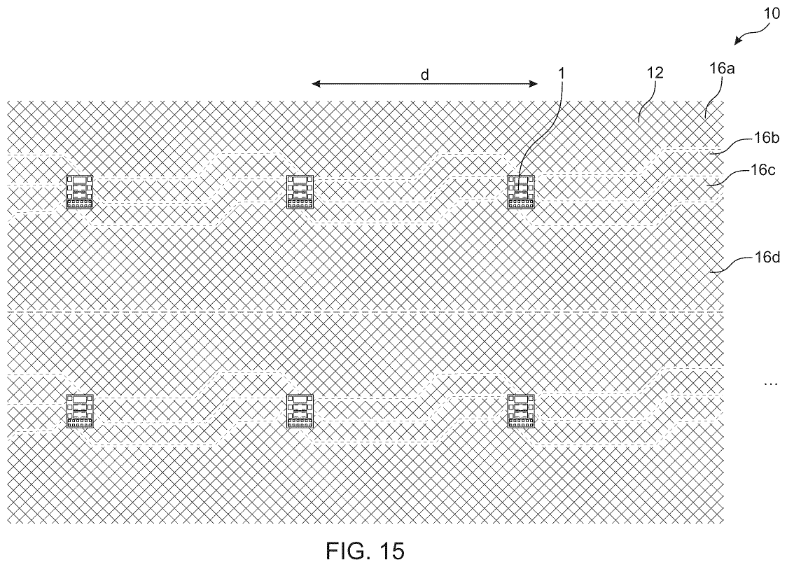

FIG. 15 shows a top view of a further embodiment of a transparent panel 10 in accordance with some embodiments of the proposed principle. In the embodiment shown, the conductive structure 12 is in form of a conductive mesh separated into portions 16a, 16b, 16c, 16d, . . . each electrically coupled to first contact pads 3a of optoelectronic components of the transparent panel 1. Such a mesh structure can be desired, as it can provide a certain transparency while providing enough conductive cross section to still be able to transmit a necessary current to the optoelectronic devices 1. The optoelectronic devices 1 can for example be arranged in an array like pattern on the carrier substrate 11 in rows and columns with a distance d between each other relating to a desired pixel distance of the later application of the transparent panel 10.

1-20. (canceled)

21. An optoelectronic device comprising:
a first integrated circuit comprising first contact pads configured for electrically contacting and/or operating the optoelectronic device and second contact pads;
a second integrated circuit arranged on the first integrated circuit comprising at least third contact pads electrically coupled to at least some of the second contact pads; and
an optoelectronic component arranged on the first or second integrated circuit and being electrically coupled to the first or second integrated circuit,
wherein the first integrated circuit comprises a first functionality configured for operating the optoelectronic component and the second integrated circuit comprises a second functionality configured for operating the optoelectronic component.

22. The optoelectronic device according to claim 21, wherein the optoelectronic component is arranged adjacent to the second integrated circuit on the first integrated circuit and electrically coupled to fourth contact pads of the first integrated circuit.

23. The optoelectronic device according to claim 21, wherein the optoelectronic component is arranged on the second integrated circuit opposite the first integrated circuit and electrically coupled to fourth contact pads of the second integrated circuit.

24. The optoelectronic device according to claim 21, wherein the optoelectronic device further comprises at least a third integrated circuit arranged adjacent to the second integrated circuit on the first integrated circuit comprising fifth contact pads and electrically coupled to at least some of the second contact pads.

25. The optoelectronic device according to claim 21, wherein the optoelectronic device further comprises at least a third integrated circuit arranged between the first and the second integrated circuit comprising fifth contact pads and electrically coupled to at least some of the third contact pads and/or the second contact pads.

26. The optoelectronic device according to claim 21, wherein the optoelectronic component and/or the second integrated circuit and/or a third integrated circuit are arranged on the same side of the first integrated circuit as the first contact pads.

27. The optoelectronic device according to claim 21, wherein the first integrated circuit and/or the second integrated circuit and/or a third integrated circuit are electrically contactable from only one of its sides.

28. The optoelectronic device according to claim 21, wherein the second integrated circuit and/or a third integrated circuit are electrically coupled to the first integrated circuit by conductive interconnects along at least one side surface of the respective integrated circuit electrically coupling at least some of the second contact pads with the third contact pads and/or fifth contact pads.

29. The optoelectronic device according to claim 21, wherein the optoelectronic component is a μ-LED.

30. The optoelectronic device according to any claim 21, further comprising a plurality of optoelectronic components arranged on the first or second integrated circuit and electrically coupled to fourth contact pads.

31. A transparent panel comprising:
at least one optoelectronic device according to claim 21; and
a transparent carrier substrate and a conductive structure arranged on the carrier substrate,
wherein the at least one optoelectronic device is arranged on the conductive structure and being electrically coupled to the same.

32. The transparent panel according to claim 31, further comprising a transparent cover layer encapsulating the optoelectronic device and the conductive structure on carrier substrate.

33. The transparent panel according to claim 31, wherein the at least one optoelectronic device is configured to emit light through the carrier substrate.

34. The transparent panel according to claim 31, wherein the conductive structure is a metal mesh arranged on the carrier substrate, wherein the metal mesh comprises a plurality of portions electrically isolated from one another, each electrically contacting a first contact pad of the at least one optoelectronic device.

35. A method for manufacturing an optoelectronic device, the method comprising:
providing a first integrated circuit substrate;
processing the integrated circuit substrate to comprise an at least first integrated circuit;
providing first and second contact pads on the at least first integrated circuit;
providing a second integrated circuit on the at least first integrated circuit comprising third contact pads electrically coupled to at least some of the second contact pads; and
providing an optoelectronic component on the at least first integrated circuit or the second intergraded circuit and electrically coupled to the first or second intergraded circuit,
wherein the first integrated circuit comprises a first functionality for operating the optoelectronic component and the second integrated circuit comprises a second functionality for operating the optoelectronic component.

36. The method according to claim 35, wherein providing the second integrated circuit on the at least first integrated circuit comprises:
providing an adhesive on the at least first integrated circuit, and
compression bonding the second integrated circuit on the at least first integrated circuit.

37. The method according to claim 35, further comprising:
back etching the integrated circuit substrate on a side opposite the second integrated circuit; and
providing a reflective coating on an etched surface.

38. The method according to claim 35, further comprising providing a temporary carrier substrate and a release layer on the integrated circuit substrate or a reflective coating on a side opposite the second integrated circuit.

39. The method according to claim 35,
wherein processing the integrated circuit substrate comprises processing to receive a plurality of first integrated circuits,
wherein providing the second integrated circuit on the at least first integrated circuit comprises providing each a second integrated circuit on each of the first integrated circuits, and
wherein providing the optoelectronic component comprises providing an optoelectronic component on a respective first integrated circuit or second intergraded circuit.

40. The method according to claim 39, further comprising separating individual optoelectronic devices, each comprising a first integrated circuit, a second integrated circuit and an optoelectronic component.
